(19) United States
(12) Patent Application Publication
(10) Pub. No.: US 2026/0269572 A1
(43) Pub. Date: Sep. 10, 2026

(54) SURFACE LIGHT-EMITTING DEVICE

(71) Applicant: Sony Group Corporation, Tokyo (JP)

(72) Inventors: Tatsuya MATOU, Kanagawa (JP); Hideki WATANABE, Kanagawa (JP); Yasutaka HIGA, Tokyo (JP); Gyongsok SONG, Kanagawa (JP); Shuhei YAMAGUCHI, Kanagawa (JP); Koshiro WADA, Kanagawa (JP); Rintaro KODA, Tokyo (JP)

(21) Appl. No.: 19/164,518

(22) PCT Filed: Mar. 22, 2024
(86) PCT No.: PCT/JP2024/011215

§ 371 Date: Sep. 11, 2025

(30) Foreign Application Priority Data
Mar. 30, 2023 (JP) 2023-056383

(51) Int. Cl. H01S 5/183

(52) U.S. Cl. CPC H01S 5/18369; H01S 5/18305

(57) ABSTRACT

[Problem] To make it possible to perform complex optical path control inside a device.

[Solution] A surface light-emitting device includes: an active layer; a first reflector that reflects light emitted by the active layer and propagating in a direction of a light-emitting surface; a second reflector that reflects light emitted by the active layer and propagating in a direction opposite from the light-emitting surface; and an insulating film disposed at least one of between the active layer and the first reflector and between the active layer and the second reflector, at least one of a film thickness or a refractive index of the insulating film changing continuously or in stages within a plane.

### TECHNICAL FIELD

The present disclosure relates to a surface light-emitting device.

### BACKGROUND ART

A Vertical Cavity Surface Emitting Laser (VCSEL) is a surface light-emitting device formed through a semiconductor process, and expectations for the use thereof are high in various fields, such as Light Detection and Ranging (LiDAR).

In VCSELs, diffraction loss generally increases as the aperture diameter decreases, causing deterioration in the I-L characteristics of the current I and the light output L. Optical path control is one way to improve the I-L characteristics. However, with a typical VCSEL, complex optical path control of a light beam is difficult. Other examples of optical path control, such as splitting the light beam from a VCSEL into a plurality of light beams to create an array of elements, or focusing a plurality of light beams into a single beam to achieve high output, are difficult to implement.

Installing an optical lens on the outside of the VCSEL is conceivable as a specific way to implement optical path control, but doing so increases the size of the device and incurs excessive manufacturing costs. Creating some kind of optical structure that acts as an optical lens inside the VCSEL is the ideal method.

One way to create an optical structure inside a VCSEL is, for example, to implant oxygen ions in the interior of the VCSEL to form an oxide film having a thickness distribution or a refractive index distribution within the plane. Since the refractive index of the oxide film is lower than that of the surrounding components, the oxide film can, depending on the shape and refractive index, effectively function as an optical lens and facilitate the optical path control mentioned above (see PTL 1 and 2).

PTL 1 discloses a method of implementing light field confinement and current confinement in the direction perpendicular to the emission direction of the VCSEL by implanting oxygen ions to form an oxide film. PTL 2 discloses a method of suppressing oscillation in higher-order modes by using oxide ion implantation to form an oxide film in the optical path of a light beam and reducing a difference between an equivalent refractive index along the optical path and an equivalent refractive index around the optical path.

### CITATION LIST

### Patent Literature

[PTL 1]
JP 2002-289967 A
[PTL 2]
JP 2005-183912 A

### SUMMARY

### Technical Problem

However, the techniques disclosed in PTL 1 and 2 do not enable complex optical path control such as reducing diffraction loss or splitting or integrating light beams.

Accordingly, the present disclosure provides a surface light-emitting device that enables complex optical path control within the device.

### Solution to Problem

To solve the above-described problems, the present disclosure provides a surface light-emitting device including:
an active layer;
a first reflector that reflects light emitted by the active layer and propagating in a direction of a light-emitting surface;
a second reflector that reflects light emitted by the active layer and propagating in a direction opposite from the light-emitting surface; and
an insulating film disposed at least one of between the active layer and the first reflector and between the active layer and the second reflector, at least one of a film thickness or a refractive index of the insulating film changing continuously or in stages within a plane.

The film thickness or the refractive index of the insulating film in a center direction of an optical path may be maximum or minimum in the plane.

The insulating film may have a uniform film thickness in the plane and a refractive index that changes continuously or in stages in the plane.

The insulating film may have a uniform refractive index in the plane and a film thickness that changes continuously or in stages in the plane.

The insulating film may be a region including at least one of oxygen ions or nitrogen ions in a semiconductor layer.

The semiconductor layer may include aluminum.

The insulating film may be surrounded by the semiconductor layer.

The insulating film may include a plurality of divided insulating films obtained by dividing the insulating film into a plurality of parts in a planar direction, and a current path connecting to the active layer may be disposed between two of the divided insulating films adjacent in the planar direction.

The two divided insulating films adjacent in the planar direction may have different film thicknesses or refractive index distributions from each other.

A plurality of the insulating films may be disposed along an optical path.

Of the plurality of insulating films, an insulating film closer to the active layer may have a smaller area than other insulating films.

The surface light-emitting device may include a first cladding layer disposed between the active layer and the first reflector; and
a second cladding layer disposed between the active layer and the second reflector,
wherein the insulating film may be disposed within at least one of the first cladding layer and the second cladding layer.

An entirety of one main surface of the insulating film may be disposed in contact with an end surface of at least one of the first cladding layer and the second cladding layer.

At least a portion of one main surface of the insulating film may be disposed within at least one of the first cladding layer and the second cladding layer.

The insulating film may include:
a first insulating film disposed between the active layer and the first reflector; and
a second insulating film disposed between the active layer and the second reflector.

The surface light-emitting device may include a first cladding layer disposed between the active layer and the first reflector; and
a second cladding layer disposed between the active layer and the second reflector,
the first insulating film may be disposed within the first cladding layer,
the second insulating film may be disposed within the second cladding layer, and
the first insulating film and the second insulating film may have a concave portion.

The insulating film may include, between the active layer and the first reflector, a first insulating film and a second insulating film disposed at a distance from each other along an optical path, and
one of the first insulating film and the second insulating film may have a concave portion, and an other of the first insulating film and the second insulating film may have a convex portion.

The first insulating film may include a plurality of the concave portions, the second insulating film may include one of the convex portions, and
the light-emitting surface may emit a plurality of light beams obtained by splitting at the plurality of concave portions.

A contact layer may be disposed between the active layer and the insulating film.

### BRIEF DESCRIPTION OF DRAWINGS

FIG. 1A is a cross-sectional view of a surface light-emitting device according to a first embodiment.

FIG. 1B is a plan view of the surface light-emitting device according to the first embodiment.

FIG. 2A is a diagram illustrating a process for manufacturing the surface light-emitting device according to the first embodiment.

FIG. 2B is a plan view corresponding to FIG. 2A.

FIG. 3A is a cross-sectional process view continuing from FIG. 2A.

FIG. 3B is a plan view corresponding to FIG. 3A.

FIG. 4A is a cross-sectional process view of a surface light-emitting device according to a second embodiment.

FIG. 4B is a cross-sectional process view continuing from FIG. 4A.

FIG. 4C is a cross-sectional process view continuing from FIG. 4B.

FIG. 4D is a cross-sectional process view continuing from FIG. 4C.

FIG. 4E is a cross-sectional process view continuing from FIG. 4D.

FIG. 5A is a cross-sectional process view of a surface light-emitting device according to a third embodiment.

FIG. 5B is a cross-sectional process view continuing from FIG. 5A.

FIG. 5C is a cross-sectional process view continuing from FIG. 5B.

FIG. 5D is a cross-sectional process view continuing from FIG. 5C.

FIG. 6A is a cross-sectional process view of a surface light-emitting device according to a fourth embodiment.

FIG. 6B is a cross-sectional process view continuing from FIG. 6A.

FIG. 6C is a cross-sectional process view continuing from FIG. 6B.

FIG. 6D is a cross-sectional process view continuing from FIG. 6C.

FIG. 7A is a cross-sectional process view of a surface light-emitting device according to a fifth embodiment.

FIG. 7B is a cross-sectional process view continuing from FIG. 7A.

FIG. 7C is a cross-sectional process view continuing from FIG. 7B.

FIG. 7D is a cross-sectional process view continuing from FIG. 7C.

FIG. 8A is a cross-sectional process view of a surface light-emitting device according to a sixth embodiment.

FIG. 8B is a cross-sectional process view continuing from FIG. 8A.

FIG. 8C is a cross-sectional process view continuing from FIG. 8B.

FIG. 9A is a cross-sectional process view of a surface light-emitting device according to a seventh embodiment.

FIG. 9B is a cross-sectional process view continuing from FIG. 9A.

FIG. 9C is a cross-sectional process view continuing from FIG. 9B.

FIG. 9D is a cross-sectional process view continuing from FIG. 9C.

FIG. 10A is a cross-sectional view of a surface light-emitting device according to an eighth embodiment.

FIG. 10B is a cross-sectional process view illustrating a process of dividing an oxide film 8 into a plurality of regions.

FIG. 11 is a cross-sectional view of a surface light-emitting device according to a ninth embodiment.

FIG. 12 is a cross-sectional view of a surface light-emitting device according to a tenth embodiment.

FIG. 13 is a diagram illustrating an example of the schematic configuration of an endoscope system.

FIG. 14 is a block diagram illustrating an example of the functional configuration of a camera and a CCU illustrated in FIG. 13.

FIG. 15 is a diagram illustrating an example of the schematic configuration of a microsurgery system.

### DESCRIPTION OF EMBODIMENTS

Embodiments of a surface light-emitting device will be described below with reference to the drawings. Although the following descriptions will focus on the main constituent elements of the surface light-emitting device, the surface light-emitting device may have constituent elements and functions that are not illustrated or described. The following descriptions are not intended to exclude constituent elements or functions that are not illustrated or described.

### First Embodiment

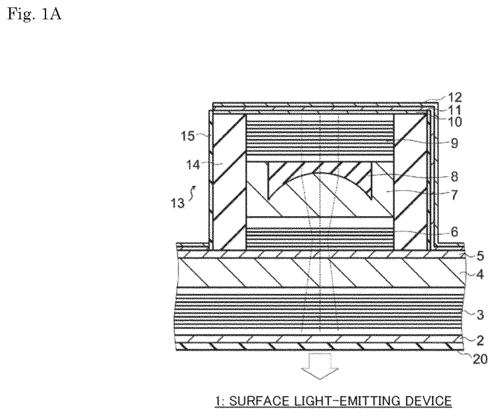

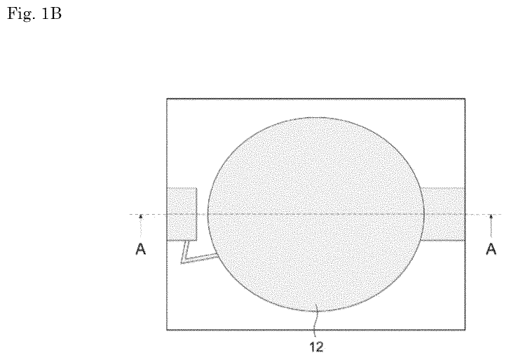

FIG. 1A is a cross-sectional view of a surface light-emitting device 1 according to a first embodiment, and FIG. 1B is a plan view of the surface light-emitting device 1 according to the first embodiment. FIG. 1A illustrates the cross-sectional structure along the direction of the line A-A in FIG. 1B.

The surface light-emitting device 1 according to the first embodiment is a layered body in which a GaAs substrate 2, a lower DBR layer 3, a lower cladding layer 4, a contact layer 5, an active layer 6, an upper cladding layer 7, an oxide film 8, an upper DBR layer 9, a contact metal layer 10, a pad metal layer 11, and a plating metal layer 12 are layered, as illustrated in FIG. 1A. The active layer 6, the upper cladding layer 7, the oxide film 8, the upper DBR layer 9, the contact metal layer 10, the pad metal layer 11, and the plating metal layer 12 constitute a mesa portion 13. An insulating layer 14 is disposed on side wall parts of the mesa portion 13, and a dielectric film 15 is layered thereon. One of the lower DBR layer 3 and the upper DBR layer 9 is a first reflector, and the other is a second reflector.

The surface light-emitting device 1 according to the first embodiment has a plurality of mesa portions 13 disposed in a planar direction along a top surface of the contact layer 5, and surface light emission is performed by a light beam generated by each mesa portion 13 being emitted from below, in FIG. 1.

The surface light-emitting device 1 according to the first embodiment reduces diffraction loss by performing optical path correction, in which the optical path with the oxide film 8 is changed, on a light beam which spreads through diffraction on a top surface side of the active layer 6. In addition, the surface light-emitting device 1 according to the first embodiment can, by the insulating layer 14, implement current confinement in the horizontal direction.

The oxide film 8 is disposed between the active layer 6 and the upper DBR layer 9, and is characterized by at least one of the film thickness or the refractive index within the plane changing continuously or in stages. More specifically, the oxide film 8 maximizes or minimizes the film thickness or refractive index in a center direction of the optical path within the plane, for example.

The oxide film 8 is formed, for example, by implanting oxygen ions in the upper cladding layer 7. Nitrogen ions may be implanted instead of oxygen ions, in which case a nitride film is formed instead of the oxide film 8. The insulative property of the oxide film 8 or the nitride film is ensured by at least one of oxidation by oxygen ions or nitridation by nitride ions in a semiconductor layer. The oxide film 8 or a nitride film that implements optical path control may be referred to as an “insulating film” herein, but an example of implementing optical path control with the oxide film 8 will mainly be described.

Although the rear surface of the GaAs substrate 2 is the light-emitting surface in FIG. 1A, the contact metal layer 10, the pad metal layer 11, and the plating metal layer 12 on the front surface side can be separated, and the front surface can be the light-emitting surface. Depending on whether the light-emitting surface of the surface light-emitting device 1 is on the front surface side or the rear surface side, the contact layer 5 on the bottom surface side of the active layer 6 is an anode or a cathode.

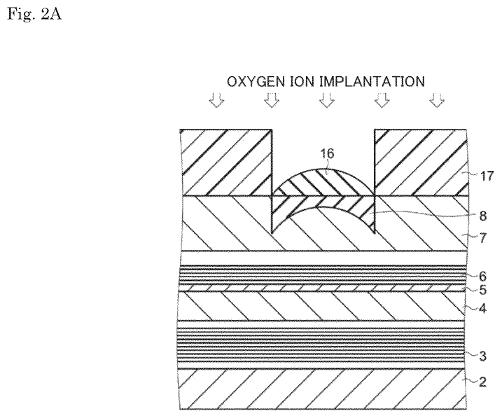

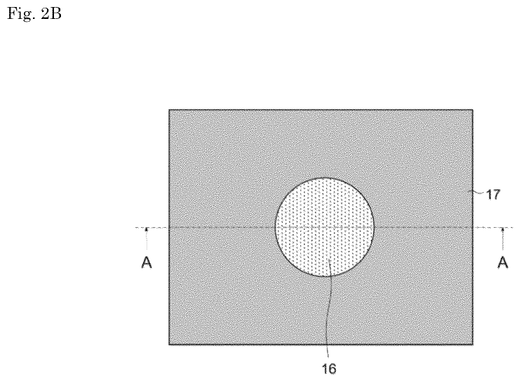

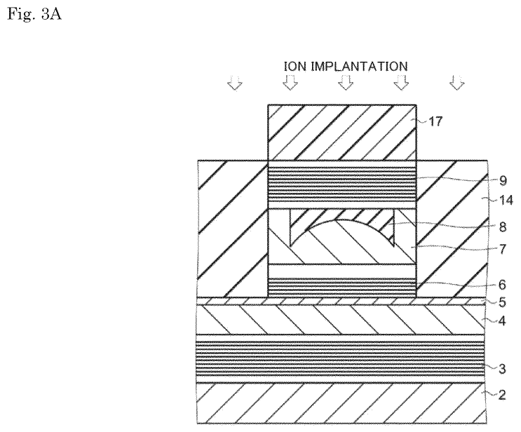

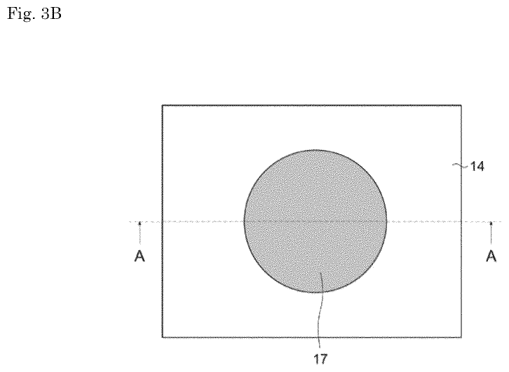

FIGS. 2A, 2B, 3A, and 3B are diagrams illustrating a process for manufacturing the surface light-emitting device 1 according to the first embodiment. FIGS. 2A and 3A illustrate cross-sectional structures during manufacture, FIG. 2B is a plan view corresponding to FIG. 2A, and FIG. 3B is a plan view corresponding to FIG. 3A. FIG. 2A illustrates the cross-sectional structure along the direction of the line A-A in FIG. 2B, and FIG. 3A illustrates the cross-sectional structure along the direction of the line A-A in FIG. 3B. These figures will be used hereinafter to describe the process for manufacturing the surface light-emitting device 1 according to the first embodiment.

Step 1: The lower DBR layer 3, the lower cladding layer 4 constituted by an AlGaAs-based semiconductor material, the contact layer 5, the active layer 6 constituted by an InGaAs-based semiconductor material having an oscillation wavelength of 920 nm to 960 nm, and the upper cladding layer 7 constituted by an AlGaAs-based semiconductor material are grown in that order on the GaAs substrate 2. The conductivity type of the contact layer 5 and the conductivity type of the upper cladding layer 7 are the opposite of each other. It is also desirable for the upper cladding layer 7 to have a high content of aluminum, which bonds strongly to oxygen atoms, such that the oxygen atoms for ion implantation do not easily diffuse within the semiconductor material. For example, keeping the aluminum content of the upper cladding layer 7 high makes it possible to form the oxide film 8 only in the region where oxygen ions are implanted. In this manner, the periphery of the oxide film 8 according to the present embodiment is covered with the upper cladding layer 7 within the plane.

Step 2: As illustrated in FIG. 2A, oxygen ions are implanted from the top surface of the upper cladding layer 7. At this time, the oxygen ions are implanted using a dielectric film 16 formed within the plane so as to be convex along the assumed optical path of the light beam and a photoresist 17 disposed around the dielectric film 16 as a mask, and as a result, a concave oxide film 8 corresponding to the shape of the dielectric film 16 is formed in the upper cladding layer 7 immediately below the dielectric film 16. Implanting the oxygen ions having arranged the peak of the dielectric film 16 along the center direction of the optical path of the mesa portion 13 ensures that the center direction of the optical path of the mesa portion 13 and the center direction of the recessed portion of the oxide film 8 coincide.

The dielectric film 16 described above is formed in advance by, for example, causing the patterned photoresist 17 to ball up and then etching over the photoresist 17.

Step 3: The dielectric film 16 is etched away, and then the upper DBR layer 9 having the same conductivity type as the upper cladding layer 7 is regrown epitaxially.

Step 4: Although not necessary, as illustrated in FIG. 3A, the insulating layer 14 may be formed on the side wall part of the upper cladding layer 7 by implanting hydrogen ions or other materials after patterning using the photoresist 17 to achieve current confinement in the horizontal direction, for example.

Step 5: The mesa portion 13 is formed. For example, the photoresist 17 is patterned such that the mesa portion 13 is shielded, and then etched up to the layer immediately before the contact layer 5 using Reactive Ion Etching (RIE), for example.

Step 6: The upper DBR layer 9 is formed on the upper cladding layer 7 and the oxide film 8. The insulating layer 14 is then formed, including the upper DBR layer 9, the upper cladding layer 7, and the active layer 6, by implanting hydrogen ions or other ions, for example, with the surface of the upper DBR layer 9 in an exposed state. Next, the contact metal layer 10 is formed on the top surface of the upper DBR layer 9 and on the contact layer 5 on the bottom surface side of the mesa portion 13, through a lift-off technique, for example. The contact metal layer 10 is formed by vacuum deposition or sputtering, for example.

Step 7: The pad metal layer 11 is formed on the top surface of the mesa portion 13 through a lift-off technique, for example. The pad metal layer 11 is formed by

Step 8: The plating metal layer 12 is formed in the same manner as the pad metal layer 11. The plating metal layer 12 is formed on at least the pad metal layer 11.

Step 9: The GaAs substrate 2 is thinned, and an SiN film 20 is formed on the rear surface of the GaAs substrate 2.

Step 10: Finally, the surface light-emitting device 1 manufactured through the manufacturing process described above is cut out from the GaAs substrate 2 into a chip, which completes the VCSEL illustrated in FIG. 1A.

In this manner, in the first embodiment, the concave oxide film 8 is formed within the upper cladding layer 7 along the center direction of the optical path of the mesa portion 13. The oxide film 8 can implement optical path control of light emitted from the active layer 6. The oxide film 8 is processed to have an external shape corresponding to the external shape of the dielectric film 16 by implanting the oxygen ions over the convex dielectric film 16, for example. By adjusting the external shape of the dielectric film 16 in advance, the oxide film 8 can be formed having any desired external shape, which makes it possible to control the optical path of the light emitted by the active layer 6 as desired and reduce diffraction loss.

### Second Embodiment

The surface light-emitting device 1 according to a second embodiment differs from the surface light-emitting device 1 according to the first embodiment in terms of the shape and arrangement of the oxide film 8.

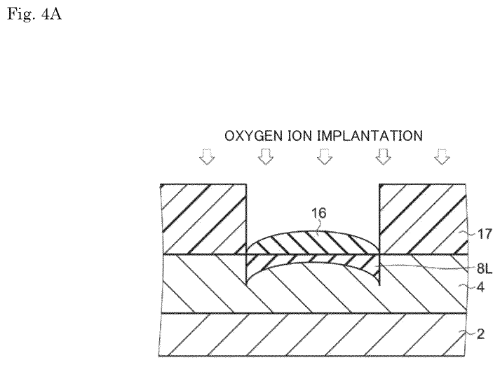

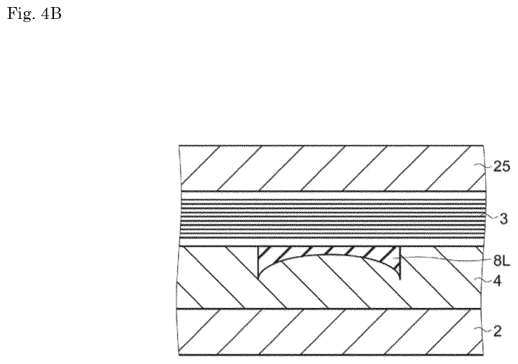

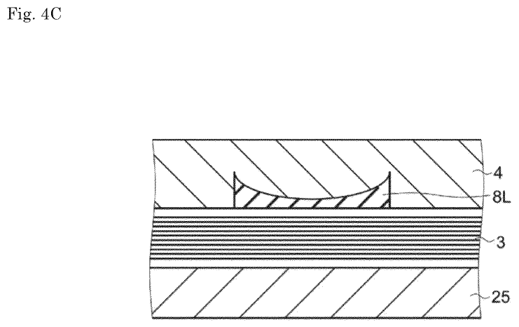

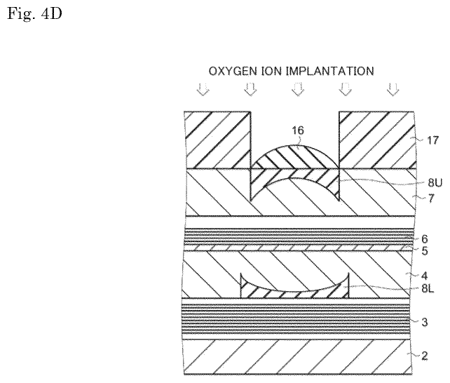

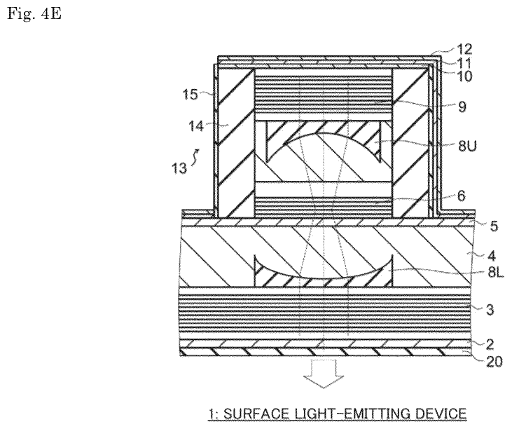

FIGS. 4A, 4B, 4C, 4D, and 4E are cross-sectional process views of the surface light-emitting device 1 according to the second embodiment. These cross-sectional process views will be used hereinafter to describe the process for manufacturing the surface light-emitting device 1 according to the second embodiment.

Step 1: As illustrated in FIG. 4A, the lower cladding layer 4 constituted by an AlGaAs-based semiconductor material is grown on the GaAs substrate 2, and as in the first embodiment, oxygen ions are implanted using the dielectric film 16 and the photoresist 17 as a mask to form a lower oxide film 8L. In this step, the aluminum content of the lower cladding layer 4 is kept high. This is because if the semiconductor layer has a high aluminum content, the strength of the bonding force between the oxygen atoms and the aluminum atoms makes it easier to maintain the shape of the lower oxide film 8L.

Step 2: Any one of the following methods is used.

As illustrated in FIG. 4B, the lower DBR layer 3 is regrown on the lower cladding layer 4, and a post substrate 25 is layered thereon. Alternatively, after the lower DBR layer 3 is grown on the post substrate 25, the lower DBR layer 3, and the lower cladding layer 4 in which the lower oxide film 8L is formed, are semiconductor-bonded.

Step 3: Next, as illustrated in FIG. 4C, after removing the GaAs substrate 2 by etching or polishing, as in the first embodiment, the contact layer 5, the active layer 6, and the upper cladding layer 7 are grown in that order, and oxygen ions are implanted using the dielectric film 16 as a mask (FIG. 4D).

Step 4: The processing of Step 3 and onward in the first embodiment is performed. The surface light-emitting device 1 having the cross-sectional structure illustrated in FIG. 4E is ultimately manufactured as a result.

In this manner, the surface light-emitting device 1 according to the second embodiment includes an upper oxide film 8U disposed on the upper cladding layer 7 and the lower oxide film 8L disposed on the lower cladding layer 4. The upper oxide film 8U and the lower oxide film 8L both have concave portions, and the concave portions are arranged facing each other. The optical path of the light emitted by the active layer 6 is controlled by the upper oxide film 8U and the lower oxide film 8L, and is incident on the upper DBR layer 9 and the lower DBR layer 3. This makes it possible to efficiently guide the light emitted by the active layer 6 to the upper DBR layer 9 and the lower DBR layer 3, and further reduce diffraction loss.

### Third Embodiment

In a third embodiment, the oxide film 8 is formed through a different method than in the first and second embodiments.

The surface light-emitting device 1 according to the present disclosure includes the oxide film 8 in which at least one of the film thickness or the refractive index distribution changes continuously or in stages in the planar direction. Even if the film thickness in the planar direction is uniform, the oxide film 8 may have a refractive index distribution in the planar direction.

In order to make the film thickness of the oxide film 8 uniform in the planar direction and provide a refractive index distribution in the plane, the oxygen ion implantation may be performed over a plurality of instances, and a relative distribution of the amount of oxygen ions implanted each time may be provided. As a result, the degree of oxidation of the oxide film 8 changes within the plane, and a refractive index distribution can be formed in the plane.

With this method, unlike the second embodiment, there is no need to provide the post substrate when forming the lower oxide film 8L, and the process for removing the GaAs substrate 2 is also unnecessary.

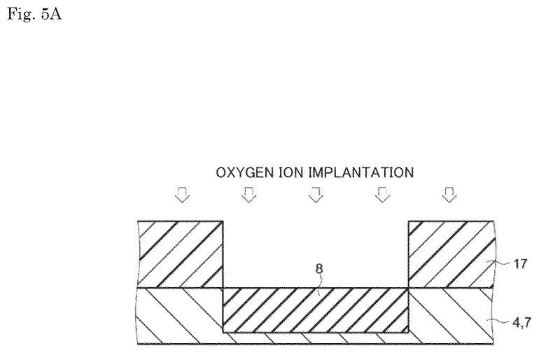

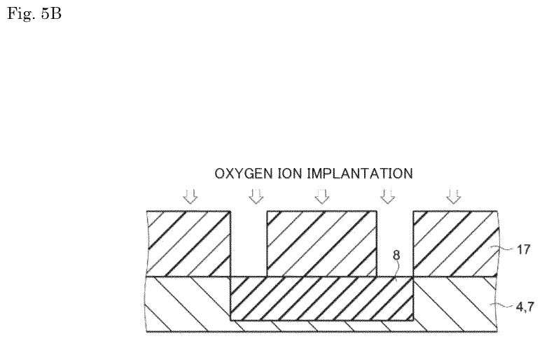

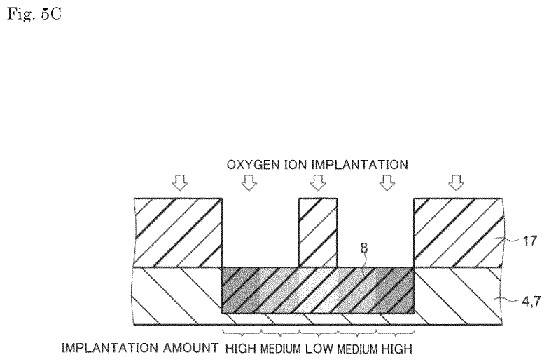

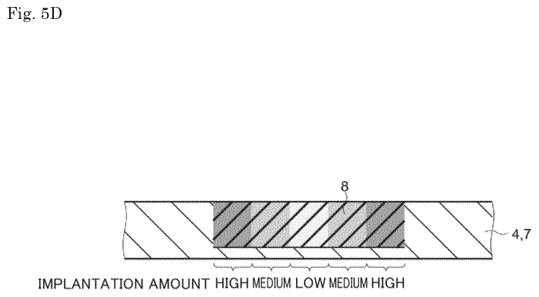

FIGS. 5A, 5B, 5C, and 5D are cross-sectional process views of the surface light-emitting device 1 according to the third embodiment. These cross-sectional process views will be used hereinafter to describe the process for manufacturing the surface light-emitting device 1 according to the third embodiment.

Step 1: As illustrated in FIG. 5A, oxygen ions are implanted throughout the region where the oxide film 8 is formed.

Step 2: As illustrated in FIG. 5B, the photoresist 17 is opened only at the region where the refractive index is to be the lowest (where the oxygen implantation amount is to be the highest), and oxygen ions are implanted for a second time.

Step 3: As illustrated in FIG. 5C, the photoresist 17 is opened only at the region where the refractive index is to be the lowest (where the oxygen implantation amount is to be the highest), and at the region where the refractive index is to be a medium level (where the oxygen implantation amount is to be the highest), and oxygen ions are implanted for a third time.

This method produces differences in the total implantation amount within the plane and changes in the degree of oxidation, which makes it possible to form an oxide film 8 having a refractive index distribution within the plane.

Alternatively, the relative implantation amount of the central portion of the oxide film 8 may be increased, in the opposite manner from that described above, to form the oxide film 8 so as to be thinner at the ends.

The oxide film 8 having the same refractive index distribution can be formed even if the above-described order of steps is changed. In other words, the oxygen implantation amount is first set to a maximum level using the photoresist 17 having a small area, as illustrated in FIG. 5C. Next, the oxygen implantation amount is set to a medium level using the photoresist 17 having a medium area, as illustrated in FIG. 5B. Finally, the oxygen implantation amount is set to a minimum level using the photoresist 17 having a large area, as illustrated in FIG. 5A.

In FIGS. 5A to 5D, ion implantation is performed by dividing the oxygen implantation amount into three stages, but any number of instances of ion implantation may be used.

In this manner, in the third embodiment, performing the ion implantation over a plurality of instances while changing the oxygen implantation amount makes it possible to form the oxide film 8 having a refractive index distribution in the planar direction while keeping the film thickness constant.

### Fourth Embodiment

In a fourth embodiment, the oxide film 8 having a thickness distribution in the planar direction is formed.

Dividing the oxygen ion implantation into a plurality of instances makes it possible to provide the oxide film 8 not only with a refractive index distribution within the plane, as in the third embodiment, but also with a thickness distribution within the plane.

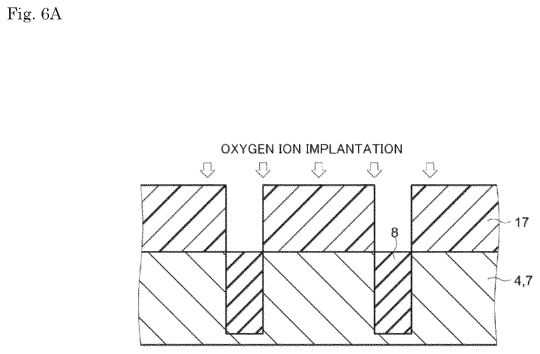

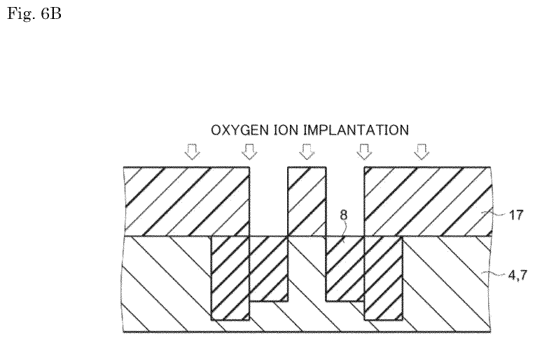

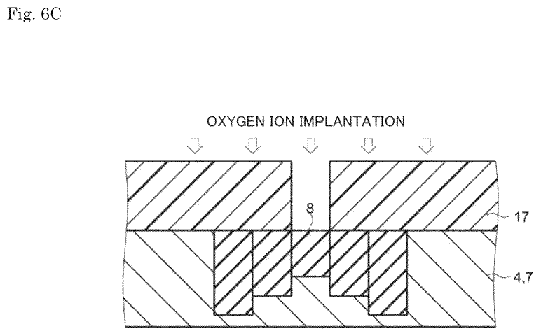

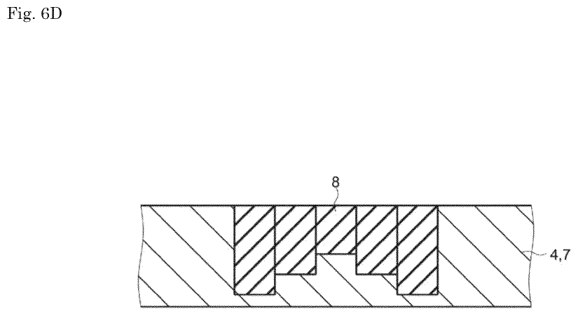

FIGS. 6A, 6B, 6C, and 6D are cross-sectional process views of the surface light-emitting device 1 according to the fourth embodiment. These cross-sectional process views will be used hereinafter to describe the process for manufacturing the surface light-emitting device 1 according to the fourth embodiment.

Step 1: As illustrated in surface light-emitting device 6A, oxygen ions are implanted with the photoresist 17 open only at the regions at the ends of the oxide film 8. At this time, the implantation energy is increased to implant the ions to a greater depth.

Step 2: As illustrated in FIG. 6B, oxygen ions are implanted for a second time with the photoresist 17 open only at the regions from the central portion to the ends of the oxide film 8. At this time, the implantation energy is set to be lower than that used during the first instance of implantation, such that the depth of ion implantation is relatively lower.

Step 3: As illustrated in FIG. 6C, oxygen ions are implanted for a third time with the photoresist 17 open only at the central region of the oxide film 8. At this time, the implantation energy is said to be even lower than that used during the first and second instances of implantation, such that the depth of ion implantation is the lowest.

Through this method, the oxide film 8 which is concave along the optical path and has a refractive index distribution can be formed, as illustrated in FIG. 6D.

Alternatively, the oxide film 8 which is concave along the optical path can be formed if the ion implantation depth is increased in the center of the oxide film 8 and reduced at the ends, in the opposite manner from that described above.

Even if the order of Steps 1 to 3 described above is changed, the final configuration will be the same. Additionally, the number of instances into which the ion implantation is divided need not be three as described above. When implantation energy is adjusted to implant ions to a greater depth, the implantation amount per unit of volume decreases, and the implantation amount is therefore increased by that amount as necessary. Conversely, when implanting ions to a lesser depth, the implantation amount is lowered as necessary.

In this manner, in the fourth embodiment, the oxide film 8 having a thickness distribution in the planar direction can be formed by performing a plurality of instances of ion implantation while changing the implantation amount of the oxygen ions. In other words, the oxide film 8 may have a uniform refractive index within the plane, as well as a film thickness that changes continuously or in stages within the plane.

### Fifth Embodiment

In the fifth embodiment, the oxide film 8 having a thickness distribution in the planar direction is formed through a different method than that used in the fourth embodiment.

In the first to fourth embodiments described above, the oxide film 8 is formed in contact with the surface of the upper cladding layer 7 or the lower cladding layer 4, but it is also possible to ensure that at least a part of the oxide film 8 is not in contact with the surface. This makes it possible to optimize the shape and arrangement location of the oxide film 8.

As the oxygen ion implantation energy is increased, the number of oxygen atoms increases at locations further from the surface, and decreases at locations closer to the surface. Additionally, adjusting the oxygen ion implantation amount makes it possible to prevent oxidization near the surface of the upper cladding present near the surface.

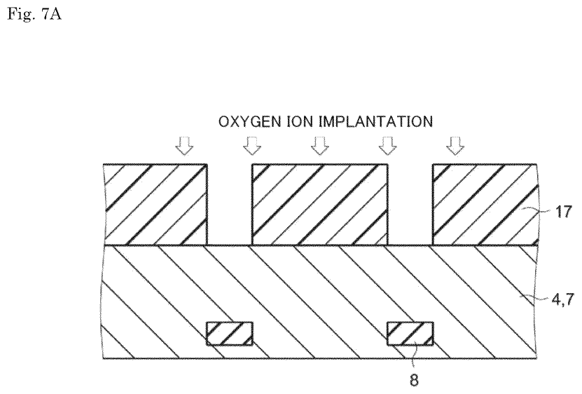

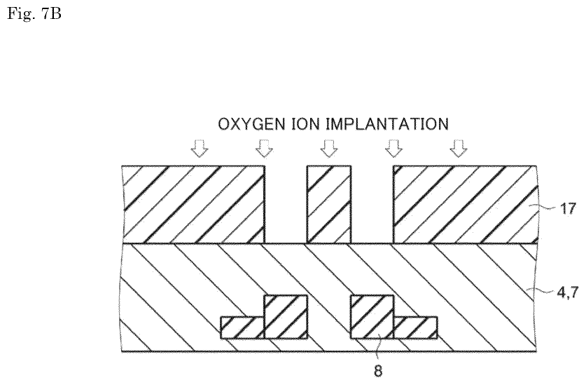

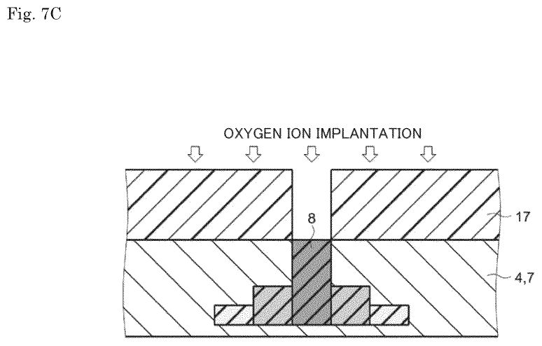

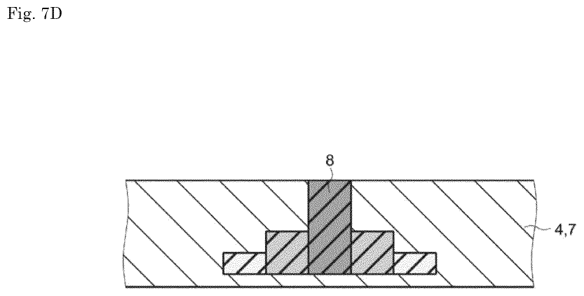

FIGS. 7A, 7B, 7C, and 7D are cross-sectional process views of the surface light-emitting device 1 according to the fifth embodiment. These cross-sectional process views will be used hereinafter to describe the process for manufacturing the surface light-emitting device 1 according to the fifth embodiment.

Step 1: As illustrated in FIG. 7A, oxygen ions are implanted with the photoresist 17 open only at the regions at the ends of the oxide film 8. At this time, the implantation energy is increased to implant oxygen ions at positions further from the surface of the upper cladding layer 7 or the lower cladding layer 4. Reducing the oxygen ion implantation amount at this time ensures that no oxygen ions are present near the surface of the upper cladding layer 7 or the lower cladding layer 4 in which the oxygen ions are implanted (“oxygen ion implantation interface” hereinafter).

Step 2: As illustrated in FIG. 7B, oxygen ions are implanted for a second time with the photoresist 17 open only at the regions from the central portion to the ends of the oxide film 8. At this time, the implantation energy is the same as in the first instance, but a relatively higher implantation amount is used to ensure oxidization up to the vicinity of the oxygen ion implantation interface.

Step 3: As illustrated in FIG. 7C, oxygen ions are implanted for a third time with the photoresist 17 open only at the central region of the oxide film 8. At this time, the implantation energy is the same as in the first and second instances, but the highest relative implantation amount is used to ensure oxidization up to the oxygen ion implantation interface.

Through this method, the convex oxide film 8, in which the refractive index distribution changes in the planar direction, can be formed, as illustrated in FIG. 7D. Alternatively, the concave oxide film 8 can be formed by reducing the oxygen ion implantation amount at the central portion of the oxide film 8 and increasing the implantation amount at the ends, in the opposite manner from that described above.

The oxide film 8 having the same shape can be formed even if the order of the steps described above is reversed, such that oxygen ions are implanted in the central portion of the oxide film 8 first, and oxygen ions are then implanted at the ends of the oxide film 8 last. The number of instances of oxygen ion implantation is not necessarily limited to three.

### Sixth Embodiment

In a sixth embodiment, a multi-beam is emitted from the mesa portion 13.

In addition to reducing the diffraction loss as described in the first embodiment and the second embodiment, the oxide film 8 can be used to cause the light beam emitted by the active layer 6 of the one mesa portion 13 to branch in to a plurality of beams within the mesa portion 13. As a result, by controlling the optical path with the oxide film 8 in the mesa portion 13 of the VCSEL, for example, each mesa portion 13 of the VCSEL can be provided with a multi-emitter configuration and emit multi-beam light.

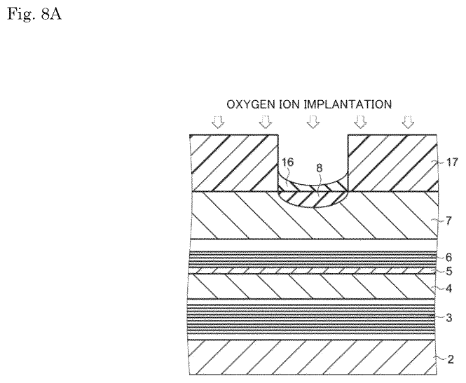

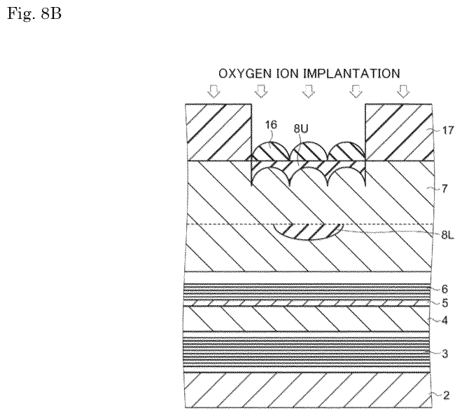

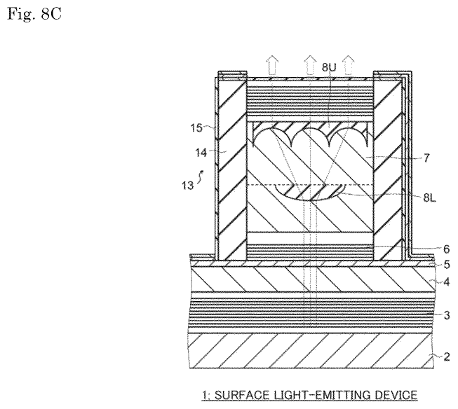

FIGS. 8A, 8B, and 8C are cross-sectional process views of the surface light-emitting device 1 according to the sixth embodiment. These cross-sectional process views will be used hereinafter to describe the process for manufacturing the surface light-emitting device 1 according to the sixth embodiment.

FIGS. 8A to 8C illustrate the process for manufacturing the surface light-emitting device 1 as a front surface-emitting type. Setting the oxide film 8 to have a smaller size in the vertical direction with proximity to the active layer 6 in the light beam emission direction and the horizontal direction of the surface light-emitting device 1 makes it easier to secure a current path to the active layer 6.

Step 1: The lower DBR layer 3, the lower cladding layer 4 constituted by an AlGaAs-based semiconductor material, the contact layer 5, the active layer 6 constituted by an InGaAs-based semiconductor material having an oscillation wavelength of 920 nm to 960 nm, and the upper cladding layer 7 constituted by an AlGaAs-based semiconductor material are grown on the GaAs substrate 2.

The conductivity type of the contact layer 5 and the conductivity type of the upper cladding layer 7 are the opposite of each other. The upper cladding layer 7 is also given a high content of aluminum, which bonds strongly to oxygen atoms, such that the oxygen atoms for ion implantation do not easily diffuse within the semiconductor.

Step 2: As illustrated in FIG. 8A, oxygen ions are implanted from the surface of the upper cladding layer 7. At this time, unlike the first embodiment, the oxygen ions are implanted using the dielectric film 16, which is formed to be concave within the plane along the assumed optical path of the light beam, and the photoresist 17 as a mask. As a result, the shape of the dielectric film 16 is reflected in the semiconductor layer immediately below the dielectric film 16, and the convex oxide film 8 is formed along the optical path.

Step 3: As illustrated in FIG. 8B, after the dielectric film 16 is etched away, the upper cladding layer 7 is regrown, and oxygen ions are implanted again using the dielectric film 16, which is formed in a convex shape within the plane on the assumed optical path of the light beam, and the photoresist 17 as a mask. As a result, the concave oxide film 8 is formed along the optical path in the semiconductor layer immediately below the dielectric film 16. The oxide film 8 has a plurality of concave portions, and each concave portion can independently guide a light beam to the light-emitting surface.

Step 4: Although not necessary, current confinement is achieved by implanting ions (which may be ions other than oxygen) after patterning using the photoresist 17, for example.

Step 5: After the dielectric film 16 is removed through wet etching, for example, the upper DBR layer 9 is formed through epitaxial growth. The conductivity type of the contact layer 5 and the conductivity type of the upper DBR layer 9 are the same. The subsequent steps are the same as those in the first embodiment.

The processing of Step 5 and onward in the first embodiment is then performed, and the surface light-emitting device 1 illustrated in FIG. 8C is ultimately manufactured. With the front surface-emitting type, SiN film formation on the rear surface of the substrate is unnecessary.

In this manner, in the sixth embodiment, modifying the shape of the oxide film 8 in the mesa portion 13 of the VCSEL makes it possible to divide the light beam emitted by the active layer 6 into a plurality of light beams in the oxide film 8 and emit those light beams, which makes a multi-emitter configuration possible.

### Seventh Embodiment

In a seventh embodiment, the active layer 6 of the mesa portion 13 is divided into a plurality of regions, a light beam is emitted for each divided part of the active layer 6, and the light beams are combined into a single light beam in the oxide film 8 and emitted.

As a method of optical path control different from those used in the first, second, and sixth embodiments, a plurality of light beams inside the mesa portion 13 can be combined into a single light beam within the mesa portion 13, for example.

As a result, even if the optical output of the light beam of a single device is insufficient for the intended application, for example, a single-emitter structure can be implemented by combining the light beams into one beam without changing the VCSEL structure aside from the oxide film 8, which enables increased output. Alternatively, if the aperture diameter is too large, biased output from the current distribution may worsen. Accordingly, the output can be increased by conversely separating the device into small aperture diameters and combining the resulting light beams into a single light beam.

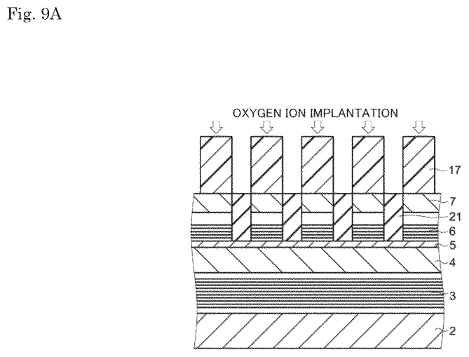

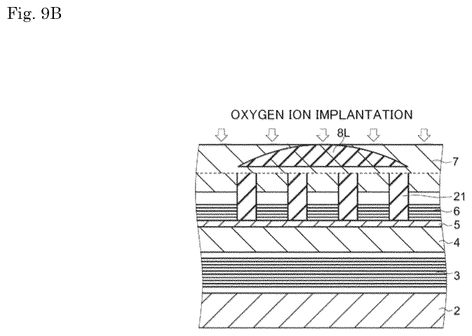

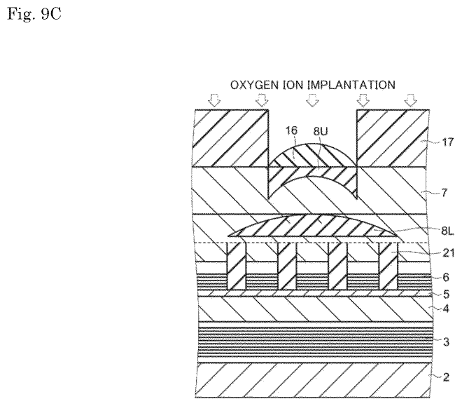

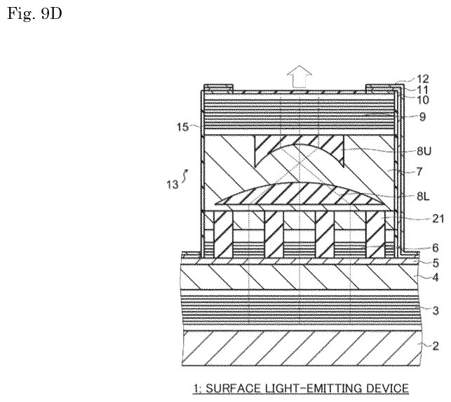

FIGS. 9A, 9B, 9C, and 9D are cross-sectional process views of the surface light-emitting device 1 according to the seventh embodiment. These cross-sectional process views will be used hereinafter to describe the process for manufacturing the surface light-emitting device 1 according to the seventh embodiment.

Step 1: The lower DBR layer 3, the lower cladding layer 4 constituted by an AlGaAs-based semiconductor material, the contact layer 5, the active layer 6 constituted by an InGaAs-based semiconductor material having an oscillation wavelength of 920 nm to 960 nm, and the upper cladding layer 7 constituted by an AlGaAs-based semiconductor material are grown on the GaAs substrate 2.

The conductivity type of the contact layer 5 and the conductivity type of the upper cladding layer 7 are the opposite of each other. The upper cladding layer 7 is also given a high content of aluminum, which bonds strongly to oxygen atoms, such that the oxygen atoms for ion implantation do not easily diffuse within the semiconductor.

Step 2: As illustrated in FIG. 9A, hydrogen ions (these may be ions other than hydrogen) for device separation are implanted from the surface of the upper cladding layer 7. The active layer 6 is divided into a plurality of divided active layers 6 as a result. An oxide film 21 is disposed between two divided active layers 6 adjacent in the planar direction.

Step 3: As illustrated in FIG. 9B, the upper cladding layer 7 is regrown, and an oxide film 8L is formed from the surface thereof, through the method according to the fifth embodiment.

Step 4: As illustrated in FIG. 9C, the upper cladding layer 7 is regrown, and oxygen ions are implanted using the dielectric film 16, which is formed in a convex shape within the plane along the assumed optical path of the light beam, and the photoresist 17 as a mask. As a result, a concave oxide film 8U is formed along the optical path in the semiconductor layer immediately below the dielectric film 16.

Step 5: After the dielectric film 16 is etched away, the upper DBR layer 9 having the same conductivity type as the upper cladding layer 7 is formed through epitaxial growth.

Step 6: The same steps as Step 5 and onward in the first embodiment are then performed, and the surface light-emitting device 1 illustrated in FIG. 9D is ultimately manufactured. With the front surface-emitting type, SiN film formation on the rear surface of the substrate is unnecessary.

In this manner, in the sixth embodiment, the active layer 6 of the mesa portion 13 is divided into a plurality or parts and a plurality of light beams are emitted, and the light beams are then combined into a single light beam in the oxide film 8 and emitted. This makes it possible to increase the light output of the light beam emitted from each mesa portion 13.

### Eighth Embodiment

In an eighth embodiment, the oxide film 8 is divided into a plurality of regions to secure a current path to the active layer 6.

The oxide film 8 is an insulator that does not allow current to pass. Accordingly, depending on the position and size of the oxide film 8, a sufficient current path to the active layer 6 cannot be secured. For this reason, the oxide film 8 is divided into a plurality of regions in the planar direction, with a gap provided between two adjacent divided oxide films 8d, and a current path is provided in this gap as necessary, to an extent which does not affect the optical path control.

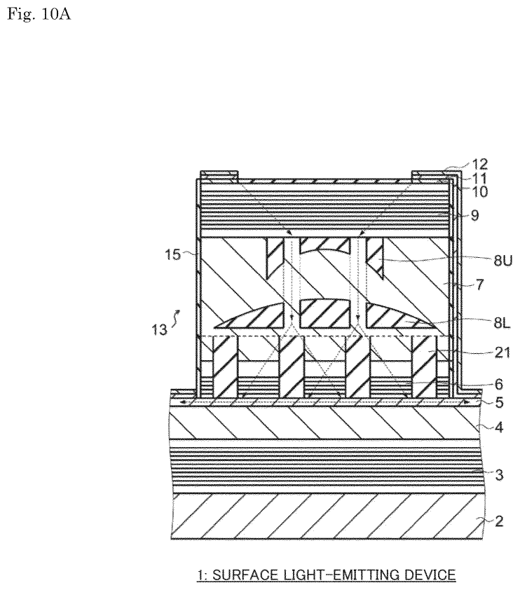

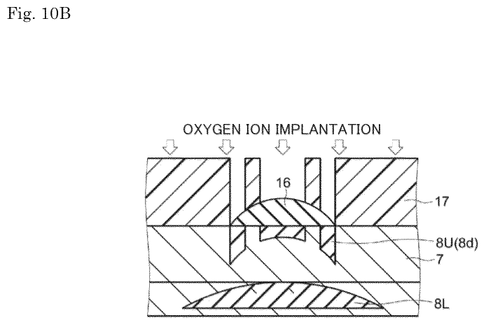

FIG. 10A is a cross-sectional view of the surface light-emitting device 1 according to the eighth embodiment, and FIG. 10B is a cross-sectional process view illustrating a process for dividing the oxide film 8 into a plurality of regions.

As illustrated in FIG. 10B, the photoresist 17 is arranged and patterned on the dielectric film 16 having a shape which follows the shape of the oxide film 8. By implanting the oxygen ions into the upper cladding layer 7 over the dielectric film 16, the oxygen ions are not implanted directly below the photoresist 17, which forms a gap between the two divided oxide films 8d. The two divided oxide films 8d adjacent in the planar direction have different film thicknesses or refractive index distributions from each other.

In this manner, the eighth embodiment includes the oxide film 8U divided into a plurality of divided oxide films 8d, and thus a current path for the active layer 6 can be provided in the gap between two divided oxide films 8d adjacent in the planar direction. Accordingly, optical path control can be performed using the plurality of divided oxide films 8d, without obstructing the current path to the active layer 6.

### Ninth Embodiment

In a ninth embodiment, a contact layer 5c is disposed between the oxide film 8 and the active layer 6.

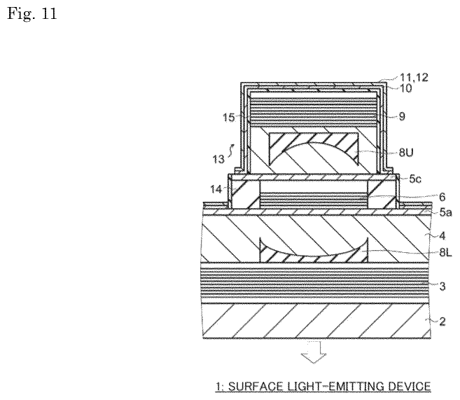

FIG. 11 is a cross-sectional view of the surface light-emitting device 1 according to a ninth embodiment. It is necessary to secure a current path between the cathode-side contact layer 5 and the active layer 6. If the cathode-side contact layer 5 is disposed between the active layer 6 and the oxide film 8, the current path between the cathode-side contact layer 5 and the active layer 6 will not be obstructed by the oxide film 8.

Accordingly, in the surface light-emitting device 1 according to the ninth embodiment, the cathode-side contact layer 5c is disposed between the active layer 6 and the oxide film 8, as illustrated in FIG. 11. The cathode-side contact metal layer 10 is connected to the cathode-side contact layer 5c. The cathode-side contact metal layer 10 is disposed to cover the side wall surfaces and top surface of the mesa portion 13. The cathode-side contact metal layer 10 is layered with the cathode-side pad metal layer 11 and the cathode-side plating metal layer 12.

FIG. 10 illustrates an example in which the cathode-side contact layer 5c is disposed between the active layer 6 and the oxide film 8, and an anode-side contact layer 5a is disposed on the opposite side. However, the anode-side contact layer 5a may be disposed between the active layer 6 and the oxide film 8, and the cathode-side contact layer 5c may be disposed on the opposite side. The upper DBR layer 9 may also be the dielectric film 16.

In this manner, in the surface light-emitting device 1 according to the ninth embodiment, the cathode- (or anode-) side contact layer 5c (or 5a) is disposed between the active layer 6 and the oxide film 8. Accordingly, the oxide film 8 does not obstruct the current path for the active layer 6 even if the oxide film 8 is not divided, and the oxide film 8 can be processed into an optimal shape for optical path control.

### Tenth Embodiment

In a tenth embodiment, a plurality of oxide films 8 having different areas are disposed on the upper cladding layer 7 and the lower cladding layer 4, respectively.

In the first to ninth embodiments, one or two oxide films 8 for optical path control are disposed on at least one of the upper cladding layer 7 or the lower cladding layer 4. However, there is a risk that the desired optical path control cannot be performed with only a small number of oxide films 8. In addition, if the desired optical path control is performed with only a small number of oxide films 8, it becomes necessary to make the shapes of the oxide films 8 complex or increase the sizes thereof, which may complicate the manufacturing process.

Accordingly, a plurality of oxide films 8 having different sizes may be disposed along the optical path.

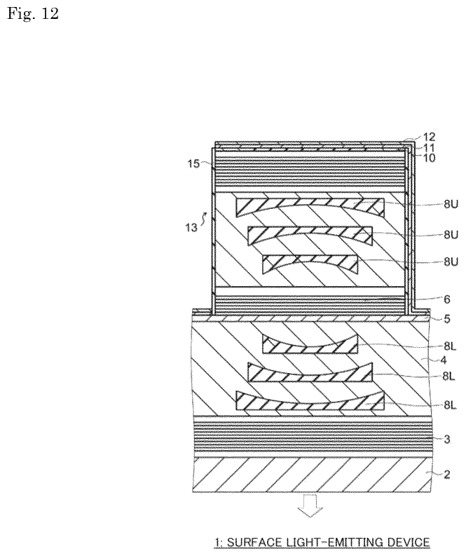

FIG. 12 is a cross-sectional view of the surface light-emitting device 1 according to the tenth embodiment. The surface light-emitting device 1 according to the tenth embodiment includes a plurality of upper oxide films 8U disposed along the optical axis of the upper cladding layer 7 and a plurality of lower oxide films 8L disposed along the optical axis of the lower cladding layer 4, as illustrated in FIG. 12.

The areas of the plurality of upper oxide films 8U decrease with proximity to the active layer 6. Likewise, the areas of the plurality of lower oxide films 8L decrease with proximity to the active layer 6. Accordingly, the upper oxide films 8U and the lower oxide films 8L do not obstruct the current path to the active layer 6.

In this manner, in the surface light-emitting device 1 according to the tenth embodiment, a plurality of oxide films 8 are disposed along the optical axis on at least one of the upper cladding layer 7 or the lower cladding layer 4.

Accordingly, optimal optical path control can be performed by adjusting the shape and position of each oxide film 8. In addition, the area of the oxide film 8, among the plurality of oxide films 8, which is close to the active layer 6 is smaller, and there is thus no risk of obstructing the current path to the active layer 6.

<<Application Example>> The technique according to the present disclosure is widely applicable to a variety of electronic devices, such as medical imaging systems, distance measurement systems such as Light Detection and Ranging (LiDAR) devices, light sources for laser machining devices, and the like. Medical imaging systems are medical systems that use imaging technology, and include endoscope systems, microscope systems, and the like, for example.

### Endoscope System

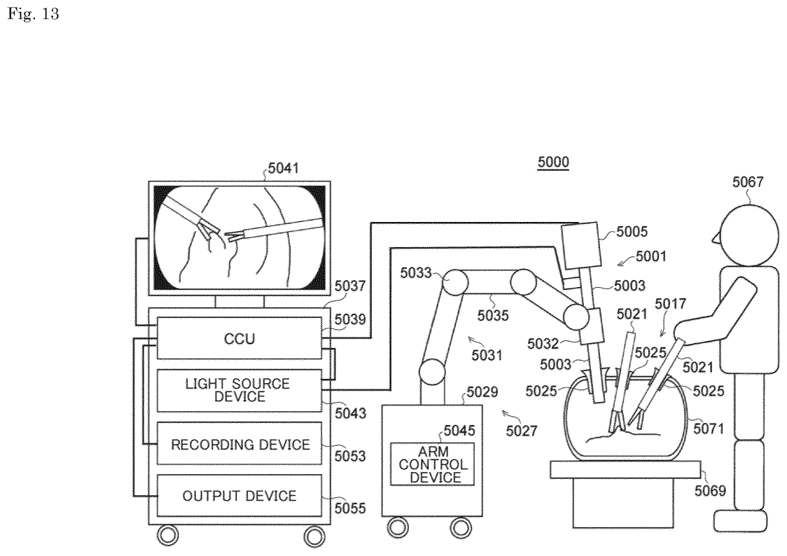

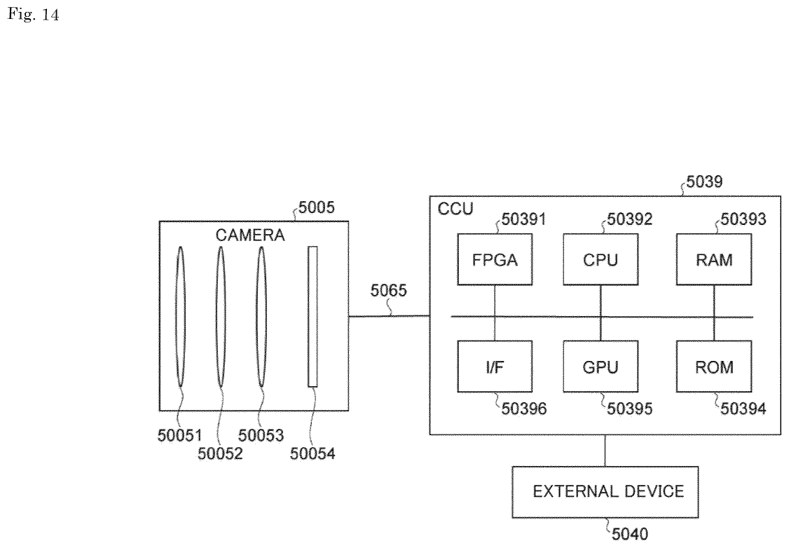

An example of an endoscope system will be described with reference to FIGS. 13 and 14. FIG. 13 is a schematic diagram illustrating an example of the configuration of an endoscope system 5000 in which the technique according to the present disclosure can be applied. FIG. 14 is a diagram illustrating an example of the configuration of an endoscope 5001 and a Camera Control Unit (CCU) 5039. FIG. 13 illustrates a state where a surgeon (e.g., a doctor) 5067, who is a participant in the operation, is performing a surgical operation on a patient 5071 on a patient bed 5069 using the endoscope system 5000. As illustrated in FIG. 13, the endoscope system 5000 is constituted by the endoscope 5001, which is a medical imaging device, the CCU 5039, a light source device 5043, a recording device 5053, an output device 5055, and a support device 5027 that supports the endoscope 5001.

In an endoscopic surgical operation, an insertion assistance implement called a trocar 5025 is inserted into the patient 5071. Furthermore, a scope 5003 and a surgical tool 5021 connected to the endoscope 5001 are inserted into the body of the patient 5071 through the trocar 5025. Examples of the surgical tool 5021 include an energy device such as an electrical scalpel, forceps, and the like.

A surgical operation image, which is a medical image captured by the endoscope 5001 and showing the interior of the body of the patient 5071, is displayed on a display device 5041. The surgeon 5067 treats a surgical operation target using the surgical tool 5021 while looking at the surgical operation image displayed on the display device 5041. Note that the medical image is not limited to a surgical operation image, and may be a diagnostic image captured during a diagnosis.

### Endoscope

As illustrated in FIG. 14, the endoscope 5001 is an imaging unit that captures an image of the inside of the body of the patient 5071, and is a camera 5005 including, for example: a focusing optical system 50051 that focuses incident light; a zoom optical system 50052 that enables optical zooming by changing the focal length of the imaging unit; a focus optical system 50053 that enables focus adjustment by changing the focal length of the imaging unit; and a light-receiving element 50054. The endoscope 5001 generates a pixel signal by focusing light onto the light-receiving element 50054 through the connected scope 5003, and outputs the pixel signal to the CCU 5039 through a transmission system. Note that the scope 5003 is an insertion portion having an objective lens at the tip, and guiding light from the connected light source device 5043 into the body of the patient 5071. The scope 5003 is a rigid scope when used with a rigid endoscope, or a flexible scope when used with a flexible endoscope, for example. The scope 5003 may be a direct-view scope or an oblique-view scope. Additionally, the pixel signal may be any signal based on the signal output from the pixel, such as a RAW signal or an image signal, for example. Additionally, the configuration may be such that a memory is installed in the transmission system that connects the endoscope 5001 and the CCU 5039, and parameters pertaining to the endoscope 5001 and the CCU 5039 are stored in the memory. The memory may be disposed, for example, in a connection portion of the transmission system or in a cable. For example, factory parameters of the endoscope 5001, parameters that change when the power is turned on, and the like may be stored in the memory of the transmission system, and the operations of the endoscope may be changed on the basis of the parameters read out from the memory. Additionally, the endoscope and the transmission system may be taken as a set and collectively referred to as an endoscope. The light-receiving element 50054 is a sensor that converts the received light into a pixel signal, and is, for example, a Complementary Metal Oxide Semiconductor (CMOS) type image sensor. The light-receiving element 50054 is preferably an image sensor having a Bayer array that is capable of shooting in color. Additionally, the light-receiving element 50054 is preferably an image sensor having a number of pixels corresponding to, for example, a resolution of 4K (3,840 horizontal pixels×2,160 vertical pixels), 8K (7,680 horizontal pixels×4,320 vertical pixels), or a square 4K (3,840 horizontal pixels or more×3,840 vertical pixels or more). The light-receiving element 50054 may be a single sensor chip, or may be a plurality of sensor chips. For example, the configuration may be such that a prism that separates incident light every predetermined wavelength band is provided, and each wavelength band is captured by a different light-receiving element. Additionally, a plurality of light-receiving elements may be provided for stereoscopic viewing. Additionally, the light-receiving element 50054 may be a sensor that includes a computation processing circuit for image processing in the chip structure, or may be a sensor for Time of Flight (ToF). Note that the transmission system is, for example, a fiber-optic cable or wireless transmission. Any wireless transmission may be used as long as the pixel signal generated by the endoscope 5001 can be transmitted. For example, the endoscope 5001 and the CCU 5039 may be connected wirelessly, or the endoscope 5001 and the CCU 5039 may be connected via a base station in the operating room. At this time, the endoscope 5001 may transmit information related to the pixel signal (e.g., the processing priority of the pixel signal, a synchronization signal, or the like) in addition to the pixel signal, at the same time. Note that a configuration may be employed where the endoscope is integrated with the scope and the camera, and the light-receiving element is provided at a tip of the scope.

### Camera Control Unit (CCU)

The CCU 5039 is a control device that comprehensively controls the connected endoscope 5001, light source device 5043, and the like, and is, for example, an information processing device that includes an FPGA 50391, a CPU 50392, a RAM 50393, a ROM 50394, a GPU 50395, and an I/F 50396, as illustrated in FIG. 14. The CCU 5039 may also comprehensively control the connected display device 5041, the recording device 5053, and the output device 5055. For example, the CCU 5039 controls an illumination timing, an illumination intensity, and a type of illumination light source of the light source device 5043. The CCU 5039 performs image processing such as development processing (e.g., demosaicing) or correction processing on the pixel signal output from the endoscope 5001, and outputs the processed pixel signal (e.g., an image) to an external device such as the display device 5041. The CCU 5039 also transmits a control signal to the endoscope 5001 to control the driving of the endoscope 5001. The control signal is, for example, information regarding imaging conditions such as the magnification, the focal length, and the like of the imaging unit. The CCU 5039 has an image down conversion function, and may be configured to be capable of simultaneously outputting a high-resolution (e.g., 4K) image to the display device 5041, and a low-resolution (e.g., HD) image to the recording device 5053.

The CCU 5039 may also be connected to an external device (e.g., a recording device, a display device, an output device, or a support device) via an IP converter that converts the signal into a predetermined communication protocol (e.g., Internet Protocol (IP)). The connection between the IP converter and the external device may be constituted by a wired network, or some or all of the network may be constructed as a wireless network. For example, the IP converter on the CCU 5039 side has a wireless communication function, and may transmit a received video to an IP switcher or an output side IP converter via a wireless communication network such as the fifth generation mobile communication system (5G) or the sixth generation mobile communication system (6G).

### Light Source Device

The light source device 5043 is a device that can radiate light of a predetermined wavelength band, and includes, for example, a plurality of light sources, and a light source optical system that guides light of the plurality of light sources. The light source is, for example, a xenon lamp, a LED light source, or an LD light source. The light source device 5043 includes LED light sources that respectively correspond to, for example, the three primary colors R, G, and B, and emit white light by controlling an output intensity or an output timing of each light source. The light source device 5043 may have a light source capable of emitting special light used for special light observation, in addition to a light source that emits normal light used for normal light observation. The special light is light of a predetermined wavelength band different from the normal light that is light for normal light observation, and is, for example, near infrared light (light whose wavelength is 760 nm or more), infrared light, blue light, and ultraviolet light. The normal light is, for example, white light or green light. According to narrow band light observation that is one type of special light observation, it is possible to image predetermined tissues such as blood vessels of a mucous surface layer with a high contrast using wavelength dependency of absorption of light in body tissues by alternately emitting blue light and green light. According to fluorescence observation that is one type of special light observation, by emitting excitation light for exciting a drug injected into the body tissues, receiving fluorescence emitted from the drug that is the body tissues or a target, and obtaining a fluorescent image, the surgeon can easily visually check the body tissues or the like that the surgeon has difficulty in visually checking using the normal light. For example, according to fluorescence observation that uses the infrared light, it is possible to make it possible to easily visually check the structure or an affected part of the body tissues by emitting infrared light having an excitation wavelength band to a drug such as Indocyanine Green (ICG) injected into the body tissues, and receiving the fluorescence of the drug. According to fluorescence observation, a drug (e.g., 5-ALA) that is excited by special light in a blue wavelength band and emits fluorescence of a red wavelength band may be used. The type of emitted light is set to the light source device 5043 under control of the CCU 5039. The CCU 5039 may have a mode in which normal light observation and special light observation are alternately performed by controlling the light source device 5043 and the endoscope 5001. At this time, information based on a pixel signal obtained by special light observation is preferably superimposed on a pixel signal obtained by normal light observation. The special light observation may be infrared light observation for emitting infrared light and observing the depth beyond an organ front surface, or multispectral observation that utilizes hyperspectral spectroscopy. Furthermore, photodynamic therapy may be used in combination.

### Recording Device

The recording device 5053 is a device that records a pixel signal (e.g., image) obtained from the CCU 5039, and is, for example, a recorder. The recording device 5053 records the image obtained from the CCU 5039 in an HDD, an SDD, or an optical disk. The recording device 5053 may be connected to a network in a hospital, and made accessible from a device outside the operating room. The recording device 5053 may also have an image down-conversion function or up-conversion function.

### Display Device

The display device 5041 is, for example, a device that can display images, and is, for example, a display monitor. The display device 5041 displays a display image based on the pixel signal obtained from the CCU 5039. By including a camera or microphone, the display device 5041 may also function as an input device that enables the input of instructions through gaze recognition, voice recognition, and gestures.

### Output Device

The output device 5055 is a device that outputs information obtained from the CCU 5039, and is, for example, a printer. The output device 5055 prints on paper a printed image based on the pixel signal obtained from the CCU 5039, for example.

### Support Device

The support device 5027 is an articulated arm that includes a base part 5029 including an arm control device 5045, an arm part 5031 that extends from the base part 5029, and a holding part 5032 that is attached to the distal end of the arm part 5031. The arm control device 5045 includes a processor such as a CPU, and controls driving of the arm part 5031 by operating according to a predetermined program. The support device 5027 controls parameters such as the length of each link 5035 that constitutes the arm part 5031, a rotation angle and a torque of each joint 5033, and the like using the arm control device 5045 to control, for example, a position and an attitude of the endoscope 5001 held by the holding part 5032. Consequently, it is possible to change the endoscope 5001 to a desired position or attitude, insert the scope 5003 into the patient 5071, and change an observation region in the body. The support device 5027 functions as an endoscope support arm that supports the endoscope 5001 during a surgical operation. As a result, the support device 5027 can serve as a substitute for a scopist who is an assistant holding the endoscope 5001. The support device 5027 may be a device that supports a microscope device 5301 (described later), and can also be referred to as a medical support arm. Note that the support device 5027 may be controlled through an autonomous control method by the arm control device 5045, or through a control method in which the arm control device 5045 is controlled on the basis of user inputs. For example, the control method may be a master-slave method in which the support device 5027 serving a slave device (replica device), which is a patient cart, is controlled on the basis of the movement of the master device (primary device), which is a surgeon console in front of the user. The support device 5027 may be able to be remotely controlled from outside the operating room.

The foregoing has described an example of an endoscope system 5000 to which the technique of the present disclosure can be applied. For example, the technique according to the present disclosure may be applied in a microscope system.

### Microscope System

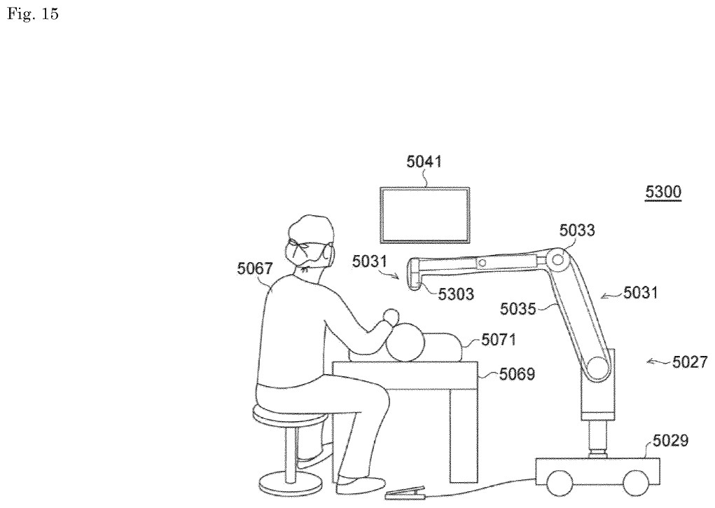

FIG. 15 is a diagram illustrating an example of the schematic configuration of a microsurgery system to which the technique according to the present disclosure is applicable. Note that in the following descriptions, elements that are the same as those of the endoscope system 5000 will be given the same reference numerals, and redundant descriptions thereof will be omitted.

FIG. 15 schematically illustrates a state where the surgeon 5067 performs a surgical operation on the patient 5071 on the patient bed 5069 by using a microsurgery system 5300. For the sake of simplicity, in FIG. 15, a cart 5037 among the configuration of the microsurgery system 5300 is not illustrated, and the microscope device 5301 is illustrated in a simplified manner instead of the endoscope 5001. In this regard, the microscope device 5301 in these descriptions may refer to a microscope unit 5303 provided at the distal end of the link 5035, or may refer to the entire configuration including the microscope unit 5303 and the support device 5027.

As illustrated in FIG. 15, using the microsurgery system 5300, at the time of surgery, an image of the surgical site captured by the microscope device 5301 is magnified and displayed on the display device 5041 installed in the operating room. The display device 5041 is installed facing a surgeon 5067, and the surgeon 5067 performs various treatments on the surgical site, such as excision of the affected site, while observing the state of the surgical site through the image projected on the display device 5041. The microsurgery system is used for eye surgery and brain surgery, for example.

An example of the endoscope system 5000 and the microsurgery system 5300 to which the technique according to the present disclosure can be applied has been described above. Note that the system to which the technique of the present disclosure can be applied is not limited to such examples. For example, the support device 5027 can also support another observation device or another surgical tool instead of the endoscope 5001 or the microscope unit 5303 at the distal end. The other observation device may be, for example, forceps, tweezers, a pneumoperitoneum tube for pneumoperitoneum, or an energy treatment instrument for incising tissues and sealing a blood vessel by cauterization. The observation device and the surgical tools are supported by the support device, so that the positions can be fixed with higher stability and the workload of the medical staff can be lighter than in manual support by the medical staff. The technique according to the present disclosure may be applied to such a support device that supports configurations other than a microscope unit.

The technique of the present disclosure can be applied favorably in the surgical tool 5021 in the configuration described above. Specifically, by irradiating the affected area of the patient with a short-pulse laser pulse from the surface light-emitting device 1 according to the present embodiment, the treatment of the affected area can be performed more safely and reliably without damaging the periphery of the affected area.

Note that the present technique can also take on the following configurations.
(1) A surface light-emitting device including:
an active layer;
a first reflector that reflects light emitted by the active layer and propagating in a direction of a light-emitting surface;
a second reflector that reflects light emitted by the active layer and propagating in a direction opposite from the light-emitting surface; and
an insulating film disposed at least one of between the active layer and the first reflector and between the active layer and the second reflector, at least one of a film thickness or a refractive index of the insulating film changing continuously or in stages within a plane.
(2) The surface light-emitting device according to (1),
wherein the film thickness or the refractive index of the insulating film in a center direction of an optical path is maximum or minimum in the plane.
(3) The surface light-emitting device according to (1) or (2),
wherein the insulating film has a uniform film thickness in the plane and a refractive index that changes continuously or in stages in the plane.
(4) The surface light-emitting device according to (1) or (2),
wherein the insulating film has a uniform refractive index in the plane and a film thickness that changes continuously or in stages in the plane.
(5) The surface light-emitting device according to any one of (1) to (4),
wherein the insulating film is a region including at least one of oxygen ions or nitrogen ions in a semiconductor layer.
(6) The surface light-emitting device according to (5),
wherein the semiconductor layer includes aluminum.
(7) The surface light-emitting device according to (5) or (6),
wherein the insulating film is surrounded by the semiconductor layer.
(8) The surface light-emitting device according to any one of (1) to (7),
wherein the insulating film includes a plurality of divided insulating films obtained by dividing the insulating film into a plurality of parts in a planar direction, and
a current path connecting to the active layer is disposed between two of the divided insulating films adjacent in the planar direction.
(9) The surface light-emitting device according to (8),
wherein the two divided insulating films adjacent in the planar direction have different film thicknesses or refractive index distributions from each other.
(10) The surface light-emitting device according to any one of (1) to (9), including:
a plurality of the insulating films disposed along an optical path.
(11) The surface light-emitting device according to (10),
wherein of the plurality of insulating films, an insulating film closer to the active layer has a smaller area than other insulating films.
(12) The surface light-emitting device according to any one of (1) to (11), including:
a first cladding layer disposed between the active layer and the first reflector; and
a second cladding layer disposed between the active layer and the second reflector,
wherein the insulating film is disposed within at least one of the first cladding layer and the second cladding layer.
(13) The surface light-emitting device according to (12),
wherein an entirety of one main surface of the insulating film is disposed in contact with an end surface of at least one of the first cladding layer and the second cladding layer.
(14) The surface light-emitting device according to (12),
wherein at least a portion of one main surface of the insulating film is disposed within at least one of the first cladding layer and the second cladding layer.
(15) The surface light-emitting device according to any one of (1) to (14),
wherein the insulating film includes:
a first insulating film disposed between the active layer and the first reflector; and
a second insulating film disposed between the active layer and the second reflector.
(16) The surface light-emitting device according to (15), including:
a first cladding layer disposed between the active layer and the first reflector; and
a second cladding layer disposed between the active layer and the second reflector,
wherein the first insulating film is disposed within the first cladding layer, the second insulating film is disposed within the second cladding layer, and
wherein the first insulating film and the second insulating film have a concave portion.
(17) The surface light-emitting device according to any one of (1) to (14),
wherein the insulating film includes, between the active layer and the first reflector, a first insulating film and a second insulating film disposed at a distance from each other along an optical path, and
one of the first insulating film and the second insulating film has a concave portion, and an other of the first insulating film and the second insulating film has a convex portion.
(18) The surface light-emitting device according to (17),
wherein the first insulating film includes a plurality of the concave portions, the second insulating film includes one of the convex portions, and
the light-emitting surface emits a plurality of light beams obtained by splitting at the plurality of concave portions. (19) The surface light-emitting device according to any one of (1) to (18), including:
a contact layer disposed between the active layer and the insulating film.

Aspects of the present disclosure are not limited to the aforementioned individual embodiments and include various modifications that those skilled in the art can achieve, and the effects of the present disclosure are also not limited to the details described above. In other words, various additions, modifications, and partial deletions can be made without departing from the conceptual ideas and spirit of the present disclosure that can be derived from the details defined in the claims and the equivalents thereof.

### REFERENCE SIGNS LIST

1 Surface light-emitting device
2 GaAs substrate
3 Lower DBR layer
4 Lower cladding layer
5 Contact layer
5a Anode-side contact layer
5c Cathode-side contact layer
6 Active layer
7 Upper cladding layer
8 Oxide film
8d Divided oxide film
8L Lower oxide film
8U Upper oxide film
9 Upper DBR layer
13 Mesa portion
14 Insulating layer
15 Dielectric film
16 Dielectric film
17 Photoresist
20 SiN film
21 Oxide film
25 Post substrate

1. A surface light-emitting device comprising:
an active layer;
a first reflector that reflects light emitted by the active layer and propagating in a direction of a light-emitting surface;
a second reflector that reflects light emitted by the active layer and propagating in a direction opposite from the light-emitting surface; and
an insulating film disposed at least one of between the active layer and the first reflector and between the active layer and the second reflector, at least one of a film thickness or a refractive index of the insulating film changing continuously or in stages within a plane.

2. The surface light-emitting device according to claim 1,
wherein the film thickness or the refractive index of the insulating film in a center direction of an optical path is maximum or minimum in the plane.

3. The surface light-emitting device according to claim 1,
wherein the insulating film has a uniform film thickness in the plane and a refractive index that changes continuously or in stages in the plane.

4. The surface light-emitting device according to claim 1,
wherein the insulating film has a uniform refractive index in the plane and a film thickness that changes continuously or in stages in the plane.

5. The surface light-emitting device according to claim 1,
wherein the insulating film is a region including at least one of oxygen ions or nitrogen ions in a semiconductor layer.

6. The surface light-emitting device according to claim 5,
wherein the semiconductor layer includes aluminum.

7. The surface light-emitting device according to claim 5,
wherein the insulating film is surrounded by the semiconductor layer.

8. The surface light-emitting device according to claim 1,
wherein the insulating film includes a plurality of divided insulating films obtained by dividing the insulating film into a plurality of parts in a planar direction, and
a current path connecting to the active layer is disposed between two of the divided insulating films adjacent in the planar direction.

9. The surface light-emitting device according to claim 8,
wherein the two divided insulating films adjacent in the planar direction have different film thicknesses or refractive index distributions from each other.

10. The surface light-emitting device according to claim 1, comprising:
a plurality of the insulating films disposed along an optical path.

11. The surface light-emitting device according to claim 10,
wherein of the plurality of insulating films, an insulating film closer to the active layer has a smaller area than other insulating films.

12. The surface light-emitting device according to claim 1, comprising:
a first cladding layer disposed between the active layer and the first reflector; and
a second cladding layer disposed between the active layer and the second reflector,
wherein the insulating film is disposed within at least one of the first cladding layer and the second cladding layer.

13. The surface light-emitting device according to claim 12,
wherein an entirety of one main surface of the insulating film is disposed in contact with an end surface of at least one of the first cladding layer and the second cladding layer.

14. The surface light-emitting device according to claim 12,
wherein at least a portion of one main surface of the insulating film is disposed within at least one of the first cladding layer and the second cladding layer.

15. The surface light-emitting device according to claim 1,
wherein the insulating film includes:
a first insulating film disposed between the active layer and the first reflector; and
a second insulating film disposed between the active layer and the second reflector.

16. The surface light-emitting device according to claim 15, comprising:
a first cladding layer disposed between the active layer and the first reflector; and
a second cladding layer disposed between the active layer and the second reflector,
wherein the first insulating film is disposed within the first cladding layer,
the second insulating film is disposed within the second cladding layer, and
wherein the first insulating film and the second insulating film have a concave portion.

17. The surface light-emitting device according to claim 1,
wherein the insulating film includes, between the active layer and the first reflector, a first insulating film and a second insulating film disposed at a distance from each other along an optical path, and
one of the first insulating film and the second insulating film has a concave portion, and an other of the first insulating film and the second insulating film has a convex portion.

18. The surface light-emitting device according to claim 17,
wherein the first insulating film includes a plurality of the concave portions, the second insulating film includes one of the convex portions, and
the light-emitting surface emits a plurality of light beams obtained by splitting at the plurality of concave portions.

19. The surface light-emitting device according to claim 1, comprising:
a contact layer disposed between the active layer and the insulating film.
